(19) United States
(12) Patent Application Publication
(10) Pub. No.: US 2018/0292696 A1
(43) Pub. Date: Oct. 11, 2018

(54) ARRAY SUBSTRATE, MANUFACTURING METHOD THEREOF, DISPLAY PANEL AND DISPLAY DEVICE

(71) Applicant: BOE Technology Group Co., Ltd., Beijing (CN)

(72) Inventor: Seungjin Choi, Beijing (CN)

(73) Assignee: BOE Technology Group Co., Ltd., Beijing (CN)

(21) Appl. No.: 15/822,623

(22) Filed: Nov. 27, 2017

(30) Foreign Application Priority Data
Apr. 7, 2017 (CN) 201710224259.8

(51) Int. Cl. G02F 1/1343; G02F 1/1362; H01L 51/52

(52) U.S. Cl. CPC G02F 1/13439; G02F 2001/136295; H01L 51/5237; G02F 1/136286

(57) ABSTRACT

The present disclosure provides an array substrate, a manufacturing method thereof, a display panel and a display device. The manufacturing method includes steps of: depositing an active layer film, a source/drain metal film and a passivation layer film sequentially onto a base substrate; and forming patterns of an active layer, a source electrode, a drain electrode and a first passivation layer through a patterning process. The pattern of the first passivation layer is identical to the patterns of the source electrode and the drain electrode. The array substrate includes the base substrate, and the active layer, the source electrode, the drain electrode and the first passivation layer arranged on the base substrate. An orthogonal projection of the first passivation layer onto the base substrate overlaps orthogonal projections of the source electrode and the drain electrode onto the base substrate.

### CROSS-REFERENCE TO RELATED APPLICATION

The present application claims a priority of the Chinese patent application No. 201710224259.8 filed on Apr. 7, 2017, which is incorporated herein by reference in its entirety.

### TECHNICAL FIELD

The present disclosure relates to the field of display technology, in particular to an array substrate, a manufacturing method thereof, a display panel and a display device.

### BACKGROUND

Recently, the display technology has been developed quickly, and a thin film transistor (TFT) has been developed from an original amorphous-silicon (a-Si) TFT to a low-temperature poly-silicon (LTPS) TFT and an oxide TFT. In the case that an active layer is made of an oxide, e.g., indium gallium zinc oxide (IGZO) or indium tin zinc oxide (ITZO), its carrier mobility is 20 to 30 times that of a-Si, so the oxide TFT has such advantages as high mobility, large on-state current, excellent switching characteristics and better uniformity, and it is able to charge or discharge a pixel electrode through the oxide TFT at a larger rate, thereby to improve a pixel response speed and acquire a larger refresh rate. Hence, the oxide TFT may be applied to a situation where rapid response and large current are required, e.g., a display device or an organic electroluminescence display device having a high frequency, a high resolution and a large size.

The oxide TFT may be manufactured through different processes, e.g., an etch stop layer (ESL)-type process and a back channel etch (BCE)-type process. Currently, the ESL-type process is relatively mature. However, for the ESL-type process, an ESL is formed on an oxide semiconductor layer, and then a via-hole is formed in the ESL through etching to connect a source electrode and a drain electrode to the active layer through the via-hole. Hence, an additional patterning process is required, and thereby the manufacture cost may increase. For the BCE-type process, although without the patterning process for forming the ESL, an etching process has relatively higher requirements and abnormalities may occur for patterns due to such problems as over-etching or even peeling-off of a photoresist, so the reliability of the TFT characteristics may be adversely affected.

### SUMMARY

In one aspect, the present disclosure provides in some embodiments a method for manufacturing an array substrate, including steps of: depositing an active layer film, a source/drain metal film and a passivation layer film sequentially onto a base substrate; and forming patterns of an active layer, a source electrode, a drain electrode and a first passivation layer through a patterning process. The pattern of the first passivation layer is identical to the patterns of the source electrode and the drain electrode.

In a possible embodiment of the present disclosure, the step of forming the patterns of the active layer, the source electrode, the drain electrode and the first passivation layer through a patterning process includes applying a photoresist onto the passivation layer film, and forming the patterns of the active layer, the source electrode, the drain electrode and the first passivation layer through a half-tone or grey-tone mask patterning process.

In a possible embodiment of the present disclosure, the step of forming the patterns of the active layer, the source electrode, the drain electrode and the first passivation layer through a half-tone or grey-tone mask patterning process includes: exposing and developing the photoresist using a half-tone or grey-tone mask plate to form an unexposed region corresponding to positions where the source electrode, the drain electrode and a data line are located, a partially-exposed region corresponding to a position where a channel is located, and a fully-exposed region corresponding to the other positions; etching off the passivation layer film, the source/drain metal film and the active layer film at the fully-exposed region; performing ashing treatment to remove the photoresist at the partially-exposed region; etching off the passivation layer film and the source/drain metal film at the partially-exposed region; and removing the remaining photoresist to form the patterns of the active layer, the source electrode, the drain electrode and the first passivation layer.

In a possible embodiment of the present disclosure, prior to the step of forming the patterns of the active layer, the source electrode, the drain electrode and the first passivation layer, the method further includes forming a gate structure layer. The step of forming the gate structure layer includes: forming patterns of a gate electrode and a gate line on the base substrate through a single-tone mask patterning process and depositing a gate insulation layer, or forming patterns of the gate electrode, the gate line and a common electrode on the base substrate through a half-tone or grey-tone mask patterning process and depositing the gate insulation layer.

In a possible embodiment of the present disclosure, subsequent to the step of forming the patterns of the active layer, the source electrode, the drain electrode and the first passivation layer, the method further includes forming a transparent electrode structure layer. The step of forming the transparent electrode structure layer includes: depositing a second passivation layer, forming a pixel electrode, which is connected to the drain electrode through a via-hole, through a patterning process, depositing a third passivation layer and forming the common electrode through a patterning process; or depositing the second passivation layer, and forming the pixel electrode, which is connected to the drain electrode through the via-hole, through a patterning process.

In a possible embodiment of the present disclosure, the active layer is made of indium gallium zinc oxide or indium tin zinc oxide, the first passivation layer is made of silicon nitride, and each of the source electrode and the drain electrode is of a structure having a first layer made of a molybdenum-niobium alloy, a second layer made of copper, and a third layer made of the molybdenum-niobium alloy.

In another aspect, the present disclosure provides in some embodiments an array substrate, including a base substrate, and an active layer, a source electrode, a drain electrode and a first passivation layer arranged on the base substrate. A pattern of the first passivation layer is identical to patterns of the source electrode and the drain electrode.

In a possible embodiment of the present disclosure, orthogonal projections of the first passivation layer, the source electrode and the drain electrode onto the base substrate are located within an orthogonal projection of the active layer onto the base substrate.

In a possible embodiment of the present disclosure, the array substrate further includes a gate structure layer. The gate structure layer includes: a gate electrode arranged on the base substrate and a gate insulation layer covering the gate electrode; or the gate electrode and a common electrode arranged on the base substrate, and the gate insulation layer covering the gate electrode and the common electrode. The active layer, the source electrode, the drain electrode and the first passivation layer are arranged on the gate insulation layer.

In a possible embodiment of the present disclosure, the array substrate further includes a transparent electrode structure layer. The transparent electrode structure layer includes: a second passivation layer covering the patterns of the active layer, the source electrode, the drain electrode and the first passivation layer, a pixel electrode arranged on the second passivation layer and connected to the drain electrode through a via-hole, a third passivation layer covering the pixel electrode and the second passivation layer, and a common electrode arranged on the third passivation layer; or the second passivation layer covering the patterns of the active layer, the source electrode, the drain electrode and the first passivation layer, and the pixel electrode arranged on the second passivation layer and connected to the drain electrode through the via-hole.

In a possible embodiment of the present disclosure, the active layer is made of indium gallium zinc oxide or indium tin zinc oxide, the first passivation layer is made of silicon nitride, and each of the source electrode and the drain electrode is of a structure having a first layer made of a molybdenum-niobium alloy, a second layer made of copper, and a third layer made of the molybdenum-niobium alloy.

In yet another aspect, the present disclosure provides in some embodiments a display panel including a first substrate and a second substrate arranged opposite to the first substrate. The first substrate is the above-mentioned array substrate.

In still yet another aspect, the present disclosure provides in some embodiments a display device including the above-mentioned display panel.

According to the array substrate, the manufacturing method thereof, the display panel and the display device in the embodiments of the present disclosure, the first passivation layer is arranged on the source electrode and the drain electrode. As a result, it is able to prevent the occurrence of over-etching or peeling-off of the photoresist in the case of forming the patterns of the active layer, the source electrode and the drain electrode through a patterning process, thereby to improve the accuracy of the patterns as well as the reliability of the TFT characteristics.

Of course, it is unnecessary for any product or method in the embodiments of the present disclosure to achieve all the above-mentioned advantages. The other features and advantages will be described hereinafter, and may become apparent or understandable partially from the embodiments of the present disclosure. The objects and the other advantages of the present disclosure may be implemented and acquired through structures specified in the description, claims and drawings.

### BRIEF DESCRIPTION OF THE DRAWINGS

The following drawings are provided to facilitate the understanding of the present disclosure, and constitute a portion of the description. These drawings and the following embodiments are for illustrative purposes only, but shall not be construed as limiting the present disclosure. Shapes and sizes of the members in the drawings are for illustrative purposes only, but shall not be used to reflect any actual scale.

FIG. 1 is a flow chart of a method for manufacturing an array substrate according to one embodiment of the present disclosure;

FIG. 2 is a schematic view showing the array substrate after the formation of a gate electrode according to one embodiment of the present disclosure;

FIG. 3 is a schematic view showing the array substrate after the deposition of an active layer film, a source/drain metal film and a passivation layer film according to one embodiment of the present disclosure;

FIG. 4 is a schematic view showing the array substrate after the application of a photoresist according to one embodiment of the present disclosure;

FIG. 5 is a schematic view showing the array substrate after the photoresist has been exposed and developed according to one embodiment of the present disclosure;

FIG. 6 is a schematic view showing the array substrate after a first etching process according to one embodiment of the present disclosure;

FIG. 7 is a schematic view showing the array substrate after an ashing process according to one embodiment of the present disclosure;

FIG. 8 is a schematic view showing the array substrate after a second etching process according to one embodiment of the present disclosure;

FIG. 9 is a schematic view showing the array substrate after the removal of the photoresist according to one embodiment of the present disclosure;

FIG. 10 is a schematic view showing the array substrate after the formation of a pixel electrode and a common electrode according to one embodiment of the present disclosure;

FIG. 11 is a schematic view showing the array substrate after the formation of the gate electrode and the common electrode according to one embodiment of the present disclosure;

FIG. 12 is another schematic view showing the array substrate after the photoresist has been exposed and developed according to one embodiment of the present disclosure;

FIG. 13 is another schematic view showing the array substrate after the first etching process according to one embodiment of the present disclosure;

FIG. 14 is another schematic view showing the array substrate after the ashing process according to one embodiment of the present disclosure;

FIG. 15 is a schematic view showing the array substrate after the second etching process and the removal of the photoresist according to one embodiment of the present disclosure; and

FIG. 16 is a schematic view showing the array substrate after the formation of the pixel electrode according to one embodiment of the present disclosure.

### DETAILED DESCRIPTION OF THE EMBODIMENTS

The present disclosure will be described hereinafter in conjunction with the drawings and embodiments. The following embodiments are for illustrative purposes only, but shall not be used to limit the scope of the present disclosure. It should be appreciated that, the embodiments of the present disclosure and the features in the embodiments may be combined in any form, in the case of no conflict.

In order to make the objects, the technical solutions and the advantages of the present disclosure more apparent, the present disclosure will be described hereinafter in a clear and complete manner in conjunction with the drawings and embodiments. Obviously, the following embodiments merely relate to a part of, rather than all of, the embodiments of the present disclosure, and based on these embodiments, a person skilled in the art may, without any creative effort, obtain the other embodiments, which also fall within the scope of the present disclosure.

Along with the increase in a size of a liquid crystal display (LCD), in the case that a signal transmission line and an electrode are each of a large resistance, such a defect as display non-uniformity may occur due to an IR drop. Usually, copper (Cu) having relatively low resistivity is adopted in the display field to manufacture the signal transmission line and the electrode. However, copper atoms may be easily diffused into an insulation layer or an oxide, so it is necessary to provide a metal barrier layer to prevent the diffusion of the copper atoms. In the related art, the metal barrier layer is usually made of titanium (Ti), molybdenum (Mo), tantalum (Ta) or a molybdenum-niobium (MoNb) alloy. For example, in the case that a source electrode and a drain electrode are made of copper, each of them may consist of three layers MoNb/Cu/MoNb, i.e., a first layer made of MoNb and serving as the metal barrier layer, a second layer made of Cu, and a third layer made of MoNb and serving as the metal barrier layer.

Usually, several patterning process need to be used for the manufacture of an oxide TFT array substrate. For example, for an array substrate with a High Advanced Dimension Switch (HADS) mode, eight or six patterning processes may be used. The eight patterning processes may include a patterning process for forming a gate electrode, a patterning process for forming an active layer, a patterning process for forming the source electrode and the drain electrode, a patterning process for forming a resin layer, a patterning process for forming a first passivation layer, a patterning process for forming a pixel electrode, a patterning process for forming a second passivation layer and a patterning process for forming a common electrode. The six patterning processes may include a patterning process for forming the gate electrode, a patterning process for forming the active layer, the source electrode and the drain electrode, a patterning process for forming the first passivation layer, a patterning process for forming the pixel electrode, a patterning process for forming the second passivation layer and a patterning process for forming the common electrode, i.e., patterns of the active layer, the source electrode and the drain electrode are formed through a single patterning process. It is found that, in the case that the patterns of the active layer, the source electrode and the drain electrode are formed through a single patterning process, such defects as over-etching and peeling-off of a photoresist may occur.

To be specific, during the formation of the patterns of the active layer, the source electrode and the drain electrode, usually a source/drain metal film may be etched through a wet-etching process, then an active layer film may be etched through a wet-etching process, and then the source/drain metal film may be etched again through an etching process. In other words, two wet-etching processes are performed before the source/drain metal film is etched again, so the adhesion between the photoresist and the metal barrier layer made of MoNb may be deteriorated, and even gaps may occur therebetween. In the case that the source/drain metal film is etched again, an etchant may enter the gaps between the photoresist and the metal barrier layer and the metal barrier layer may corrode. At this time, such defects as over-etching and peeling-off of the photoresist may occur.

In order to solve the above-mentioned problems, the present disclosure provides in some embodiments a method for manufacturing an array substrate which, as shown in FIG. 1, includes steps of: depositing an active layer film, a source/drain metal film and a passivation layer film sequentially onto a base substrate; and forming patterns of an active layer, a source electrode, a drain electrode and a first passivation layer through a patterning process, The pattern of the first passivation layer is identical to the patterns of the source electrode and the drain electrode, i.e., an orthogonal projection of the first passivation layer onto the base substrate coincides with orthogonal projections of the source electrode and the drain electrode onto the base substrate.

According to the method in the embodiments of the present disclosure, through the first passivation layer on the source electrode and the drain electrode, it is able to prevent the occurrence of over-etching or peeling-off of the photoresist in the case of forming the patterns of the active layer, the source electrode and the drain electrode through a patterning process, thereby to improve the accuracy of the patterns as well as the reliability of the TFT characteristics.

The method specifically includes: Step S1 of depositing the active layer film, the source/drain metal film and the passivation layer film sequentially onto the base substrate; and Step S2 of applying a photoresist onto the passivation layer film, and forming the patterns of the active layer, the source electrode, the drain electrode and the first passivation layer through a half-tone or grey-tone mask patterning process. The pattern of the passivation layer is identical to the patterns of the source electrode and the drain electrode.

Step S2 includes: Step S21 of applying the photoresist onto the passivation layer film; Step S22 of exposing and developing the photoresist using a half-tone or grey-tone mask plate to form an unexposed region corresponding to positions where the source electrode, the drain electrode and a data line are located, a partially-exposed region corresponding to a position where a channel is located, and a fully-exposed region corresponding to the other positions; Step S23 of etching off the passivation layer film, the source/drain metal film and the active layer film at the fully-exposed region; Step S24 of performing ashing treatment to remove the photoresist at the partially-exposed region; Step S25 of etching off the passivation layer film and the source/drain metal film at the partially-exposed region; and Step S26 of removing the remaining photoresist to form the patterns of the active layer, the source electrode, the drain electrode and the first passivation layer. The pattern of the first passivation layer is identical to the patterns of the source electrode and the drain electrode.

Step S23 includes etching off the passivation layer film at the fully-exposed region through a dry-etching process, and etching off the source/drain metal film and the active layer film at the fully-exposed region through a wet-etching process.

During the implementation, prior to the step of forming the patterns of the active layer, the source electrode, the drain electrode and the first passivation layer, the method further includes forming a gate structure layer. Subsequent to the step of forming the patterns of the active layer, the source electrode, the drain electrode and the first passivation layer, the method further includes forming a transparent electrode structure layer.

The manufacture of the array substrate will be further described hereinafter in more details.

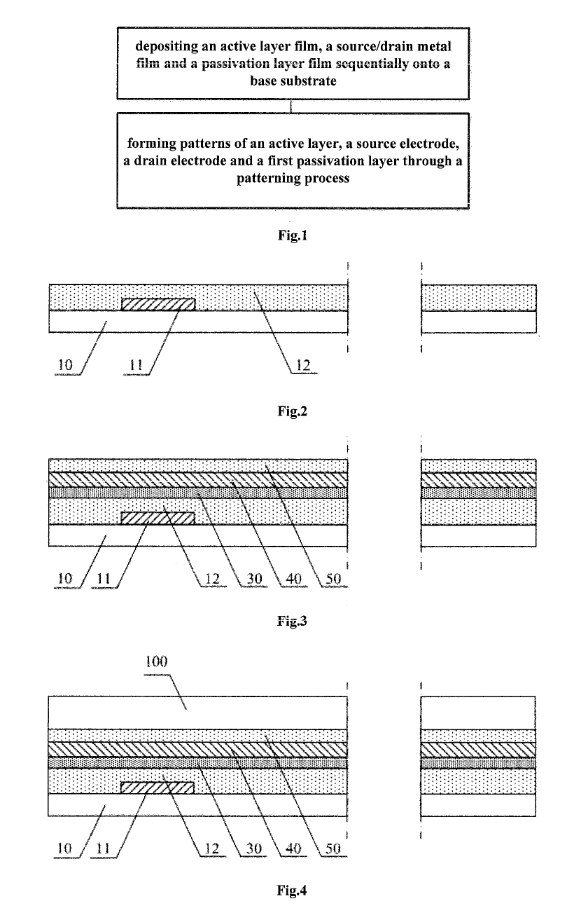

FIGS. 2-10 are schematic views showing the manufacture of the array substrate with an HADS mode. The HADS mode, on the basis of an ADS mode, has a large aperture ratio and a wide viewing angle up to 178°. The method for manufacturing the array substrate will be described hereinafter in conjunction with FIGS. 2-10. In these drawings, a left portion refers to a region of the array substrate where TFTs are arranged, and a right portion refers to a region of the array substrate where data lines are arranged. In the embodiments of the present disclosure, the so-called “patterning process” may refer to a known, mature manufacture process, and it may include deposition of layers, application of photoresist, exposing with a mask plate, developing, etching, and the removal of photoresist. Any known deposition process, e.g., sputtering, evaporation, or chemical vapor deposition, may be adopted. Any known application process and any known etching process may be adopted, which will not be particularly defined herein.

In a first patterning process, the gate structure layer may be formed on the base substrate. In the embodiments of the present disclosure, the gate structure layer includes a gate electrode, a gate line and a gate insulation layer. The step of forming the gate structure layer includes depositing a gate metal film onto the base substrate 10, applying the photoresist onto the gate metal film, exposing and developing the photoresist with a single-tone mask plate, etching the gate metal film and removing the remaining photoresist to form patterns of the gate electrode 11 and the gate line, and depositing the gate insulation layer 12, as shown in FIG. 12. The gate metal film may be made of copper, aluminium or molybdenum. The gate insulation layer may be a silicon oxide layer, or consist of any two or three of a silicon oxide layer, a silicon oxynitride layer and a silicon nitride layer.

In a second patterning process, the patterns of the active layer, the source electrode and the drain electrode may be formed on the base substrate with the gate structure layer through a half-tone or grey-tone mask patterning process. To be specific, the active layer film 30, the source/drain metal film 40 and the passivation layer film 50 may be deposited sequentially onto the base substrate 10 with the gate structure layer, as shown in FIG. 3. The active layer film 30 may be made of indium gallium zinc oxide, indium tin zinc oxide or any other metal oxide having semiconductor properties. The source/drain metal film 40 may be of a triple-layered structure, i.e., MoNb/Cu/MoNb. The passivation layer 50 may be made of silicon nitride or silicon oxide. In order to ensure the adhesion between the passivation layer film, which is not in direct contact with the active layer film, and the photoresist, the passivation layer film may be made of silicon nitride and have a thickness of 500 to 1000 Å.

Next, the photoresist 100 may be applied onto the passivation layer film 50, as shown in FIG. 4.

Next, the photoresist 100 may be exposed and developed with a half-tone or grey-tone mask plate to form the unexposed region C corresponding to the positions where the source electrode, the drain electrode and the data line are located, the partially-exposed region B corresponding to the position where the channel is located, and the fully-exposed region A corresponding to the other positions, as shown in FIG. 5. The photoresist at the unexposed region C has a first thickness, the photoresist at the partially-exposed region B has a second thickness smaller than the first thickness, and no photoresist is located at the fully-exposed region A.

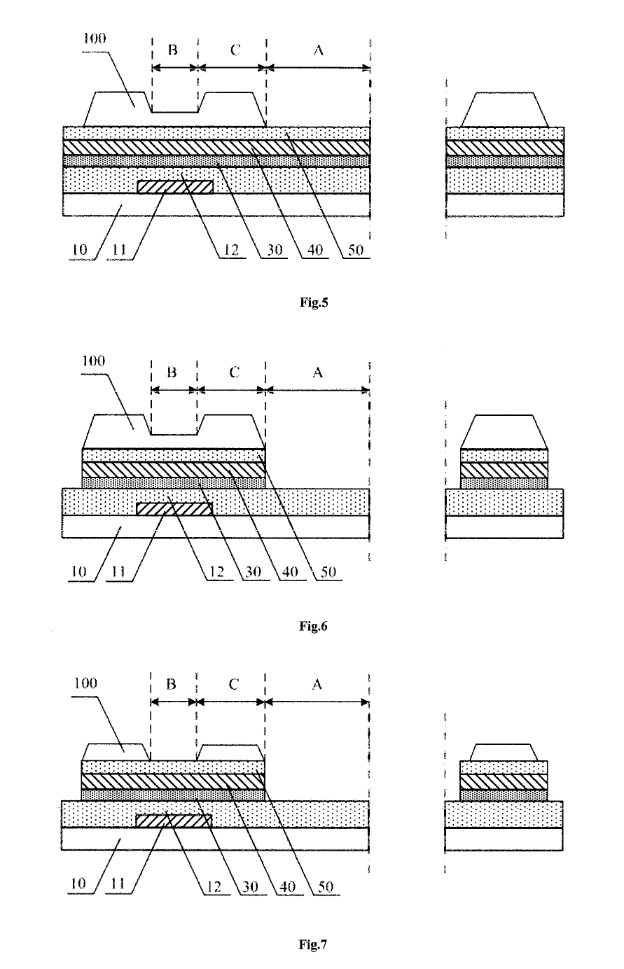

Next, the passivation layer film 50 at the fully-exposed region A may be etched off through a dry-etching process, and then the source/drain metal film 40 and the active layer film 30 at the fully-exposed region A may be etched off through a wet-etching process, as shown in FIG. 6.

Next, the photoresist 100 may be subjected to ashing treatment to remove a portion of the entire photoresist 100 having the second thickness, i.e., remove the portion of the photoresist at the partially-exposed region B to expose the region where the channel is to be formed, and reduce the thickness of the portion of the photoresist at the unexposed region C, as shown in FIG. 7.

Next, the passivation layer film 50 and the source/drain metal film 40 at the partially-exposed region B may be etched off to form a channel region, as shown in FIG. 8. The photoresist at the unexposed region C may be removed to form the patterns of the active layer 13, the source/drain electrodes 14, and the data line 20, and the first passivation layer 15 may cover the source/drain electrodes 14, as shown in FIG. 9. The pattern of the first passivation layer 15 may be identical to the patterns of the source/drain electrodes 14.

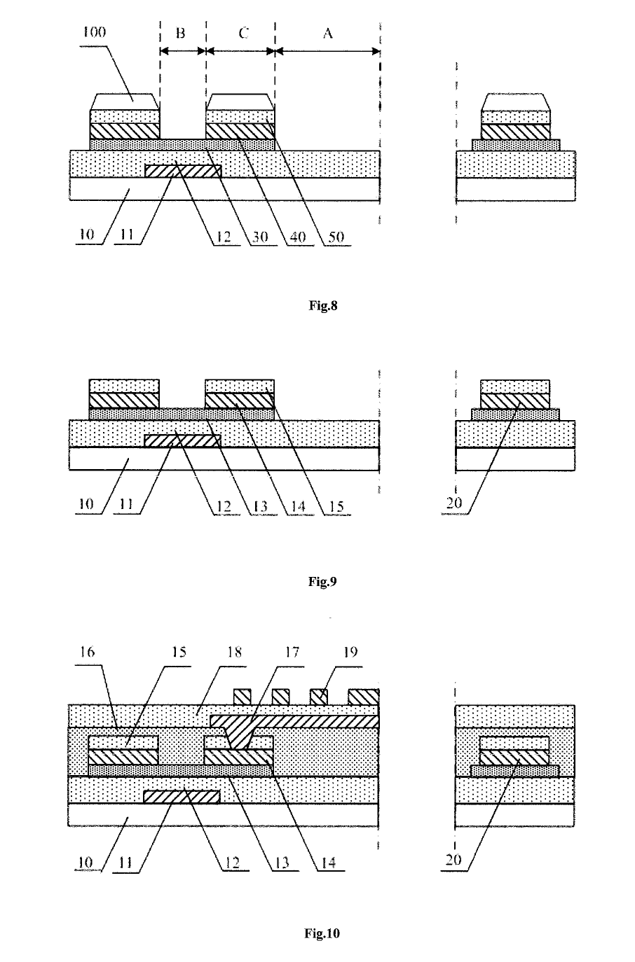

Then, the transparent electrode structure layer may be formed through a subsequent patterning process. The transparent electrode structure layer may include a second passivation layer, a pixel electrode, a third passivation layer and a common electrode. To be specific, as shown in FIG. 10, the second passivation layer 16 may be deposited in such a manner as to cover the entire base substrate 10. Next, the pixel electrode 17 may be formed through a single-tone mask patterning process and connected to the drain electrode through a via-hole. Next, the third passivation layer 18 may be deposited in such a manner as to cover the entire base substrate 10. Finally, the slit-like common electrode 19 may be formed through a single-tone mask patterning process.

During the implementation, the second passivation layer and the third passivation layer may each be a silicon oxide layer or a silicon nitride layer, or consist of any two or three of a silicon oxide layer, a silicon oxynitride layer and a silicon nitride layer. The pixel electrode and the common electrode may each be made of a transparent conductive material, e.g., indium tin oxide (ITO) or indium zinc oxide (IZO).

According to the method in the embodiments of the present disclosure, through the first passivation layer on the source electrode and the drain electrode, the photoresist is in direct contact with the first passivation layer during the formation of the patterns of the active layer, the source electrode and the drain electrode. As a result, it is able to increase the adhesion between the photoresist and the first passivation layer and prevent the occurrence of over-etching or peeling-off of the photoresist, thereby to improve the accuracy of the patterns as well as the reliability of the TFT characteristics.

FIGS. 11 to 16 are schematic views showing the manufacture of the array substrate with an ADS mode. For the ADS mode, a multi-dimensional electric field may be formed by means of electric fields generated at edges of slit electrodes within an identical plane and an electric field generated between a slit electrode layer and a plate electrode layer to enable all the liquid crystal molecules between the slit electrodes and right above the electrodes within a liquid crystal cell to rotate, thereby to improve the operational efficiency of the liquid crystal molecules and enhance the light transmission efficiency. The ADS technology may be used to improve the image quality of a display device, and has such advantages as high resolution, high transmittance, low power consumption, wide viewing angle, high aperture ratio, low chromatic aberration and free of push Mura. The method for manufacturing the array substrate will be described hereinafter in more details in conjunction with FIGS. 11 to 16.

In a first patterning process, the gate structure layer may be formed on the base substrate. In the embodiments of the present disclosure, the gate structure layer includes the gate electrode, the gate line, the common electrode and the gate insulation layer. To be specific, as shown in FIG. 11, the gate metal film and a transparent conductive film may be deposited onto the base substrate 10. Next, the photoresist may be applied thereto, and then exposed and developed using a half-tone or grey-tone mask plate to form an unexposed region corresponding to the positions where the gate electrode and the gate line are located, a partially-exposed region corresponding to the position where the common electrode is located, and a fully-exposed region corresponding to the other positions. Next, the gate metal film and the transparent conductive film at the fully-exposed region may be etched off. Next, the ashing treatment may be performed to remove the photoresist at the partially-exposed region, thereby to expose the portion of the gate metal film above the common electrode and etch off the portion of the gate metal film at the partially-exposed region. Next, the remaining photoresist may be removed to form the patterns of the gate electrode 11, the gate line and the common electrode 19, and the portion of the transparent conductive film below the gate electrode 11 may be reserved. Then, the gate insulation layer 12 may be deposited in such a manner as to cover the entire base substrate 10.

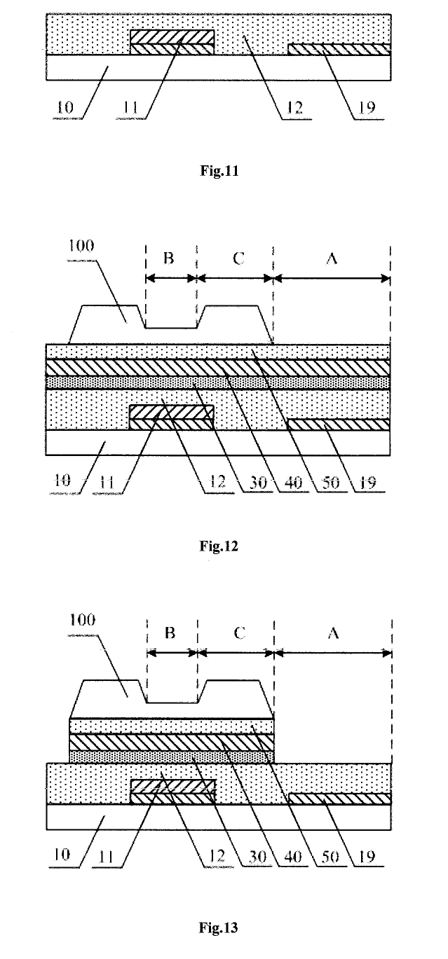

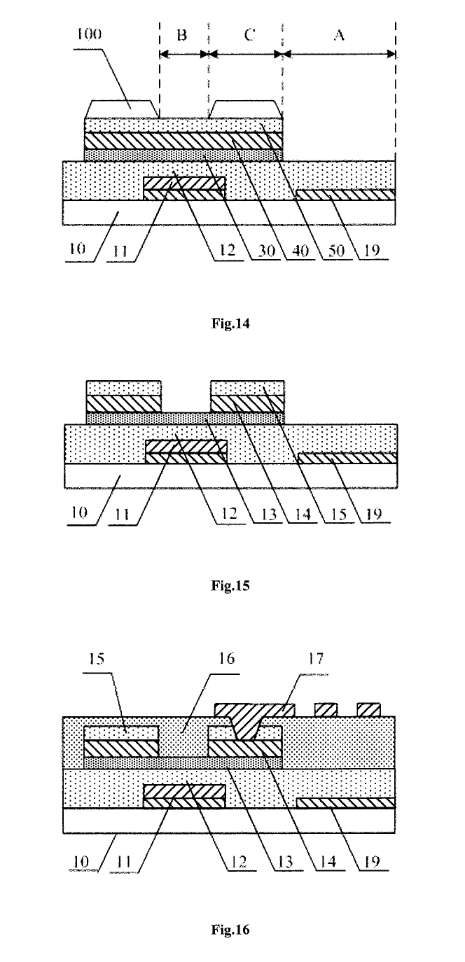

In a second patterning process, the patterns of the active layer, the source electrode and the drain electrode may be formed on the base substrate with the gate structure layer through a half-tone or grey-tone mask patterning process. To be specific, the active layer film 30, the source/drain metal film 40 and the passivation layer film 50 may be deposited sequentially onto the base substrate 10 with the gate structure layer. Next, the photoresist 100 may be applied onto the passivation layer film 50, and then exposed and developed using a half-tone or grey-tone mask plate to form the unexposed region C corresponding to the positions where the source electrode, the drain electrode and the data line are formed, the partially-exposed region B corresponding to the position where the channel is formed, and the fully-exposed region A corresponding to the other positions, as shown in FIG. 12. The photoresist at the unexposed region C has a first thickness, the photoresist at the partially region B has a second thickness smaller than the first thickness, and no photoresist is provided at the fully-exposed region A. Next, the passivation layer film 50 at the fully-exposed region A may be etched off through a dry-etching process, and the source/drain metal film 40 and the active layer film 30 may be etched off through a wet-etching process, as sown in FIG. 13. Next, the photoresist 100 may be subjected to ashing treatment to remove the photoresist at the partially-exposed region B, thereby to expose the channel region, as shown in FIG. 14. Next, the passivation layer film 50 and the source/drain metal film 40 at the partially-exposed region B may be etched off. Then, the photoresist at the unexposed region C may be removed to form the patterns of the active layer 13, the source/drain electrodes 14 and the first passivation layer 15, as shown in FIG. 15.

Then, the transparent electrode structure layer may be formed through a subsequent patterning process. The transparent electrode structure layer includes the second passivation layer and the pixel electrode. To be specific, the second passivation layer 16 may be deposited in such a manner as to cover the entire base substrate 10. Next, the slit-like pixel electrode 17 may be formed through a single-tone mask patterning process and connected to the drain electrode through a via-hole, as shown in FIG. 16.

The materials and the thickness of the films as well as the principle for preventing the occurrence of over-etching have been described hereinabove, and thus will not be particularly defined herein.

Based on an identical inventive concept, the present disclosure further provides in some embodiments an array substrate with an HADS mode. As shown in FIG. 10, the array substrate includes: the base substrate 10; the gate electrode 11 arranged on the base substrate 10; the gate insulation layer 12 covering the gate electrode 11; the active layer 13, the source/drain electrodes 14 and the first passivation layer arranged on the gate insulation layer, the pattern of the first passivation layer being identical to the patterns of the source/drain electrodes; the second passivation layer 16 covering the active layer 13, the source/drain electrodes 14 and the first passivation layer 15; the pixel electrode 17 arranged on the second passivation layer 16 and connected to the drain electrode through a via-hole; the third passivation layer 18 covering the pixel electrode 16; and the slit-like common electrode 19 arranged on the third passivation layer 18.

Orthogonal projections of the patterns of the first passivation layer and the source/drain electrodes onto the base substrate are located within an orthogonal projection of the active layer onto the base substrate, i.e., the patterns of the active layer, the source/drain electrodes and the first passivation layer are formed through a single half-tone or grey-tone mask patterning process.

The active layer may be made of IGZO, ITZO or any other metal oxide having semiconductor properties. The source/drain electrodes may each be of a triple-layered structure consisting of a MoNb layer, a Cu layer and a MoNb layer. The first passivation layer may be made of silicon nitride or silicon oxide, and preferably silicon nitride, and have a thickness of 500 to 1000 Å. The gate electrode may be made of copper, aluminium or molybdenum. The gate insulation layer, the second passivation layer and the third passivation layer may each be a silicon oxide layer, or any two or three of a silicon oxide layer, a silicon oxynitride layer and a silicon nitride layer. The pixel electrode and the common electrode may each be made of ITO or IZO.

According to the array substrate with the HADS mode in the embodiments of the present disclosure, through the first passivation layer on the source electrode and the drain electrode, it is able to prevent the occurrence of over-etching or peeling-off of the photoresist in the case of forming the patterns of the active layer, the source electrode and the drain electrode through a patterning process, thereby to improve the accuracy of the patterns as well as the reliability of the TFT characteristics.

Based on an identical inventive concept, the present disclosure further provides in some embodiments an array substrate with an ADS mode. As shown in FIG. 16, the array substrate includes: the base substrate 10; the gate electrode 11 and the plate-like common electrode 19 arranged on the base substrate 10; the gate insulation layer 12 covering the gate electrode 11 and the common electrode 19; the active layer 13, the source/drain electrodes 14 and the first passivation layer 15 arranged on the gate insulation layer, the pattern of the first passivation layer being identical to the patterns of the source/drain electrodes; the second passivation layer 16 covering the active layer 13, the source/drain electrodes 14 and the first passivation layer 15; and the slit-like pixel electrode 17 arranged on the second passivation layer 16 and connected to the drain electrode through a via-hole.

Orthogonal projections of the patterns of the first passivation layer and the source/drain electrodes onto the base substrate are located within an orthogonal projection of the active layer onto the base substrate, i.e., the patterns of the active layer, the source/drain electrodes and the first passivation layer are formed through a single half-tone or grey-tone mask patterning process.

The active layer may be made of IGZO, ITZO or any other metal oxide having semiconductor properties. The source/drain electrodes may each be of a triple-layered structure consisting of a MoNb layer, a Cu layer and a MoNb layer. The first passivation layer may be made of silicon nitride or silicon oxide, and preferably silicon nitride, and have a thickness of 500 to 1000 Å. The gate electrode may be made of copper, aluminium or molybdenum. The gate insulation layer, the second passivation layer and the third passivation layer may each be a silicon oxide layer, or any two or three of a silicon oxide layer, a silicon oxynitride layer and a silicon nitride layer. The pixel electrode and the common electrode may each be made of ITO or IZO.

According to the array substrate with the ADS mode in the embodiments of the present disclosure, through the first passivation layer on the source electrode and the drain electrode, it is able to prevent the occurrence of over-etching or peeling-off of the photoresist in the case of forming the patterns of the active layer, the source electrode and the drain electrode through a patterning process, thereby to improve the accuracy of the patterns as well as the reliability of the TFT characteristics.

Based on an identical inventive concept, the present disclosure further provides in some embodiments a BCE-type oxide TFT, including: a base substrate; a gate electrode arranged on the base substrate; a gate insulation layer covering the gate electrode; an active layer arranged on the gate insulation layer; a source electrode and a drain electrode arranged on the active layer, a channel being formed between the source electrode and the drain electrode; and a first passivation layer arranged on the source electrode and the drain electrode, a pattern of the first passivation layer being identical to patterns of the source electrode and the drain electrode. Orthogonal projections of the first passivation layer, the source electrode and the drain electrode onto the base substrate are located within an orthogonal projection of the active layer onto the base substrate, i.e., the patterns of the active layer, the source electrode, the drain electrode and the first passivation layer are formed through a single half-tone or grey-tone mask patterning process.

The active layer may be made of IGZO, ITZO or any other metal oxide having semiconductor properties. The source/drain electrodes may each be of a triple-layered structure consisting of a MoNb layer, a Cu layer and a MoNb layer. The first passivation layer may be made of silicon nitride or silicon oxide, and preferably silicon nitride, and have a thickness of 500 to 1000 Å. The gate electrode may be made of copper, aluminium or molybdenum. The gate insulation layer, the second passivation layer and the third passivation layer may each be a silicon oxide layer, or any two or three of a silicon oxide layer, a silicon oxynitride layer and a silicon nitride layer.

According to the oxide TFT in the embodiments of the present disclosure, through the first passivation layer on the source electrode and the drain electrode, it is able to prevent the occurrence of over-etching or peeling-off of the photoresist in the case of forming the patterns of the active layer, the source electrode and the drain electrode through a patterning process, thereby to improve the accuracy of the patterns as well as the reliability of the TFT characteristics.

The present disclosure further provides in some embodiments a display panel including a first substrate and a second substrate arranged opposite to the first substrate. The first substrate is the above-mentioned array substrate. The display panel may be any product or member having a display function, such as a mobile phone, a flat-panel computer, a television, a display, a laptop computer, a digital photo frame or a navigator.

The present disclosure further provides in some embodiments a display device including the above-mentioned oxide TFT. The display device may be an LCD display panel or an organic light-emitting diode (OLED) display panel.

In the embodiments of the present disclosure, such words as “in the middle of”, “under/below”, “front”, “back”, “vertical”, “horizontal”, “top”, “bottom”, “inside” and “outside” are used to indicate directions or positions as viewed in the drawings, and they are merely used to facilitate the description in the present disclosure, rather than to indicate or imply that a device or member must be arranged or operated at a specific position.

Unless otherwise specified, such words as “arrange” and “connect” have a general meaning, e.g., the word “connect” may refer to fixed connection, removable connection or integral connection, or mechanical or electrical connection, or direct connection or indirect connection via an intermediate component, or communication between two components. The meanings of these words may be understood by a person skilled in the art in accordance with the practical need.

The above are merely the preferred embodiments of the present disclosure, but the present disclosure is not limited thereto. Obviously, a person skilled in the art may make further modifications and improvements without departing from the spirit of the present disclosure, and these modifications and improvements shall also fall within the scope of the present disclosure.

What is claimed is:

1. A method for manufacturing an array substrate, comprising steps of:
depositing an active layer film, a source/drain metal film and a passivation layer film sequentially onto a base substrate; and
forming patterns of an active layer, a source electrode, a drain electrode and a first passivation layer through a patterning process,
wherein an orthogonal projection of the first passivation layer onto the base substrate overlaps orthogonal projections of the source electrode and the drain electrode onto the base substrate.

2. The method according to claim 1, wherein the step of forming the patterns of the active layer, the source electrode, the drain electrode and the first passivation layer through a patterning process comprises applying a photoresist onto the passivation layer film, and forming the patterns of the active layer, the source electrode, the drain electrode and the first passivation layer through a half-tone or grey-tone mask patterning process.

3. The method according to claim 2, wherein the step of forming the patterns of the active layer, the source electrode, the drain electrode and the first passivation layer through a half-tone or grey-tone mask patterning process comprises:
exposing and developing the photoresist using a half-tone or grey-tone mask plate to form an unexposed region corresponding to positions where the source electrode, the drain electrode and a data line are located, a partially-exposed region corresponding to a position where a channel is located, and a fully-exposed region corresponding to the other positions;
etching off the passivation layer film, the source/drain metal film and the active layer film at the fully-exposed region;
performing ashing treatment to remove the photoresist at the partially-exposed region;
etching off the passivation layer film and the source/drain metal film at the partially-exposed region; and
removing the remaining photoresist to form the patterns of the active layer, the source electrode, the drain electrode and the first passivation layer.

4. The method according to claim 1, wherein prior to the step of forming the patterns of the active layer, the source electrode, the drain electrode and the first passivation layer, the method further comprises forming patterns of a gate electrode and a gate line on the base substrate through a single-tone mask patterning process and depositing a gate insulation layer.

5. The method according to claim 1, wherein prior to the step of forming the patterns of the active layer, the source electrode, the drain electrode and the first passivation layer, the method further comprises forming patterns of a gate electrode, a gate line and a common electrode on the base substrate through a half-tone or grey-tone mask patterning process and depositing a gate insulation layer.

6. The method according to claim 1, wherein subsequent to the step of forming the patterns of the active layer, the source electrode, the drain electrode and the first passivation layer, the method further comprises depositing a second passivation layer, forming a pixel electrode, which is connected to the drain electrode through a via-hole, through a patterning process, depositing a third passivation layer and forming a common electrode through a patterning process.

7. The method according to claim 1, wherein subsequent to the step of forming the patterns of the active layer, the source electrode, the drain electrode and the first passivation layer, the method further comprises depositing a second passivation layer, and forming a pixel electrode, which is connected to the drain electrode through a via-hole, through a patterning process.

8. The method according to claim 1, wherein each of the source electrode and the drain electrode is of a structure having a first layer made of a molybdenum-niobium alloy, a second layer made of copper, and a third layer made of the molybdenum-niobium alloy.

9. An array substrate, comprising:
a base substrate, and
an active layer, a source electrode, a drain electrode and a first passivation layer arranged on the base substrate,
wherein an orthogonal projection of the first passivation layer onto the base substrate overlaps orthogonal projections of the source electrode and the drain electrode onto the base substrate.

10. The array substrate according to claim 9, wherein orthogonal projections of the first passivation layer, the source electrode and the drain electrode onto the base substrate are located within an orthogonal projection of the active layer onto the base substrate.

11. The array substrate according to claim 9, further comprising a gate structure layer, wherein the gate structure layer comprises a gate electrode arranged on the base substrate and a gate insulation layer covering the gate electrode, and the active layer, the source electrode, the drain electrode and the first passivation layer are arranged on the gate insulation layer.

12. The array substrate according to claim 9, further comprising a gate structure layer, wherein the gate structure layer comprises a gate electrode and a common electrode arranged on the base substrate, and a gate insulation layer covering the gate electrode and the common electrode, and
wherein the active layer, the source electrode, the drain electrode and the first passivation layer are arranged on the gate insulation layer.

13. The array substrate according to claim 9, further comprising a transparent electrode structure layer, wherein the transparent electrode structure layer comprises:
a second passivation layer covering patterns of the active layer, the source electrode, the drain electrode and the first passivation layer,
a pixel electrode arranged on the second passivation layer and connected to the drain electrode through a via-hole,
a third passivation layer covering the pixel electrode and the second passivation layer, and
a common electrode arranged on the third passivation layer.

14. The array substrate according to claim 9, further comprising a transparent electrode structure layer, wherein the transparent electrode structure layer comprises:
a second passivation layer covering patterns of the active layer, the source electrode, the drain electrode and the first passivation layer, and
a pixel electrode arranged on the second passivation layer and connected to the drain electrode through a via-hole.

15. The array substrate according to claim 9, wherein each of the source electrode and the drain electrode is of a structure having a first layer made of a molybdenum-niobium alloy, a second layer made of copper, and a third layer made of the molybdenum-niobium alloy.

16. A display panel comprising a first substrate and a second substrate arranged opposite to the first substrate, wherein the first substrate is the array substrate according to claim 9.

17. A display device comprising the display panel according to claim 16.
